(19) United States
(12) Patent Application Publication
(10) Pub. No.: US 2016/0041872 A1
(43) Pub. Date: Feb. 11, 2016

(54) SEMICONDUCTOR MEMORY DEVICE

(71) Applicant: SK hynix Inc., Gyeonggi-do (KR)

(72) Inventors: Young-Jun KU, Gyeonggi-do (KR); Tae-Sik YUN, Gyeonggi-do (KR)

(21) Appl. No.: 14/570,851

(22) Filed: Dec. 15, 2014

(30) Foreign Application Priority Data
Aug. 7, 2014 (KR) 10-2014-0101563

(51) Int. Cl. G06F 11/10; G11C 29/52

(52) U.S. Cl. CPC G06F 11/1068; G11C 29/52

(57) ABSTRACT

A semiconductor memory device includes: a core block suitable for storing write data as normal data or a part of combined data according to a data masking signal, and masking information indicating data masking of the combined data; and an error correcting code (ECC) block suitable for performing an ECC decoding operation on the normal data, and bypassing the ECC decoding operation on the combined data according to the masking information, wherein the combined data further includes masked data.

### CROSS-REFERENCE TO RELATED APPLICATIONS

The present application claims priority of Korean Patent Application No. 10-2014-0101563, filed on Aug. 7, 2014, which is incorporated herein by reference in its entirety.

### BACKGROUND

1. Field

Exemplary embodiments of the present invention relate to a semiconductor designing technology, and more particularly, to a semiconductor memory device for performing write and read operations for processing data and an Error Correcting Code (ECC) operation.

2. Description of the Related Art

FIG. 1 is a block diagram illustrating a general semiconductor system.

Referring to FIG. 1, a memory 110 of the semiconductor system performing an Error Correcting Code (ECC) operation includes cells for storing data and parity bits. When an ECC mode is activated, the memory 110 stores data DATA and a parity bit PARITY applied from a memory controller 130. As the memory 110 outputs the stored data DATA and the parity bit PARITY through a read operation, the memory controller 130 detects an error of the data DATA based on the parity bit PARITY. When the ECC mode is deactivated, the memory 110 receives the data DATA from the memory controller 130.

A memory 110 having a data masking function changes the data stored in normal cells, and maintains the data stored in masked cells during a write operation. Through the data masking function, the original data in the masked cells are kept unchanged while the original data in the normal cells are changed by writing new data in the normal cells, thereby preventing change in the original data of the masked cells. During the data masking operation, it is important to reflect the data change of the normal cells into the corresponding parity bits. It takes more time to perform the writing operation with the data masking function since the parity bit is also changed according to the data change of the normal cells. Since there is a time difference between the writing operations with and without the data masking function the CAS to CAS Delay time tCCD has to be controlled according to the write operations with and without the data masking function. A semiconductor memory device successively receives read and write commands RD and WT, which are column command signals. In this regard, a time interval between successive CAS (column access strobe) signals may be referred to as the tCCD. In a semiconductor memory device, lines for transferring data may be precharged to a constant voltage. The time tCCD may be related to this requirement, and may be defined as a time interval between when one column select signal YI is activated to transfer data, and when the next column select signal YI is activated to transfer data after respective lines are precharged again. For stable data transfer, a stable precharging operation may be completed within the time tCCD.

As to the memory 110 supporting a signal tCCD for both of the unmasked data in the normal cell and the masked data in the masked cells, it is hard to change data and reflect the data change to the parity bit during the tCCD, which causes data errors during write operations.

### SUMMARY

Exemplary embodiments of the present invention are directed to a semiconductor memory device for reducing the time required for an error correcting code (ECC) operation by storing whether a data masking function is performed during a write operation and controlling an output path of data based on whether the data masking function is performed during a read operation.

In accordance with an embodiment of the present invention, a semiconductor memory device may include: a core block suitable for storing write data as normal data or a part of combined data according to a data masking signal, and a masking information indicating a data masking of the combined data; and an error correcting code (ECC) block suitable for performing an ECC decoding operation on the normal data, and bypassing the ECC decoding operation on the combined data according to the masking information, wherein the combined data further includes masked data.

The semiconductor memory device may further include: a data masking (DM) information generation block suitable for generating the masking information based on the data masking signal.

The ECC block may include: a parity generation unit suitable for generating a parity bit corresponding to the write data; an ECC unit suitable for performing the ECC decoding on the normal data based on the parity bit; and a path control unit suitable for transferring the combined data to an external device, and the normal data to the ECC unit according to the masking information.

The core block may include; a data storage unit suitable for storing the normal data and the combined data; and a parity storage unit suitable for storing the parity bit and the masking information.

The path control unit may transfer the normal data and the parity bit to the ECC unit when the masking information is disabled, and the combined data to the external device when the masking information is enabled.

In accordance with another embodiment of the present invention, a semiconductor memory device may include: a core block suitable for storing write data as normal data or a part of combined data according to a data masking signal; a data masking (DM) information generation block suitable for generating masking information indicating data masking of the combined data based on the data masking signal; and an ECC block suitable for performing an ECC decoding operation on the normal data, and bypassing the ECC decoding operation on the combined data according to the masking information, wherein the combined data further includes masked data.

The core block may store the write data as the normal data when the data masking signal is disabled and store the write data as the part of the combined data when the data masking signal is enabled.

The ECC block may include: a parity generation unit suitable for generating a parity bit corresponding to the write data; an ECC unit suitable for performing the ECC decoding on the normal data based on the parity bit; and a path control unit suitable for transferring the combined data to an external device, and the normal data to the ECC unit according to the masking information.

The core block may include: a data storage unit suitable for storing the normal data and the combined data; and a parity storage unit suitable for storing the parity bit and the masking information.

The path control unit may transfer the normal data and the parity bit to the ECC unit when the masking information is disabled, and the combined data to the external device when the masking information is enabled.

In accordance with another embodiment of the present invention, a semiconductor memory device may include: a data storage block suitable for storing normal data, on which a data masking operation is not performed, and combined data, on which the data masking operation is partly performed; a parity storage block suitable for storing parity bits corresponding to the normal data and the combined data, respectively; and an error correcting code (ECC) block suitable for performing an ECC decoding operation on the normal data, and bypassing the ECC decoding operation on the combined data, wherein the combined data further includes masked data.

The semiconductor memory device may further include: a data masking (DM) information generation block suitable for generating data masking information corresponding to the combined data.

The parity storage block may further store the data masking information.

The ECC block may include: an ECC unit suitable for performing the ECC decoding on the normal data based on the parity bit corresponding to the normal data; and a path control unit suitable for transferring the combined data to an external device, and the normal data to the ECC unit according to the masking information.

The ECC block may further include: a parity generation unit suitable for generating the parity bits.

The masked data is original data stored in the data storage block.

In accordance with another embodiment of the present invention, a method for operating a semiconductor memory device may include: storing write data as normal data or a part of combined data in a data storage block according to a data masking signal; generating a parity bit corresponding to the write data, and storing the parity bit in a parity storage block; and transferring the combined data to an external device, and performing an ECC decoding on the normal data based on the parity bit according to the masking information, wherein the combined data further includes masked data.

The performing of the ECC decoding may detect and correct an error of the normal data.

### BRIEF DESCRIPTION OF THE DRAWINGS

FIG. 1 is a block diagram illustrating a general semiconductor system.

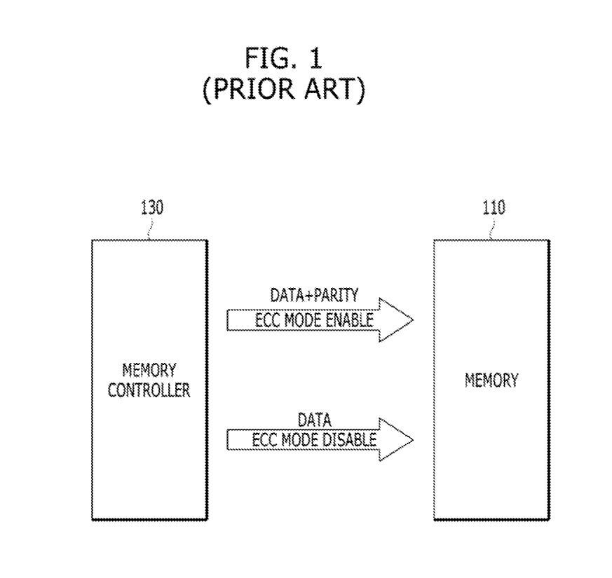

FIG. 2 is a block diagram illustrating a semiconductor memory device in accordance with an embodiment of the present invention.

### DETAILED DESCRIPTION

Exemplary embodiments of the present invention are described below in more detail with reference to the accompanying drawings. These embodiments are provided so that this disclosure is thorough and complete, and fully conveys the scope of the present invention to those skilled in the art. All “embodiments” referred to in this disclosure refer to embodiments of the inventive concept disclosed herein. The embodiments presented are merely examples and are not intended to limit the inventive concept.

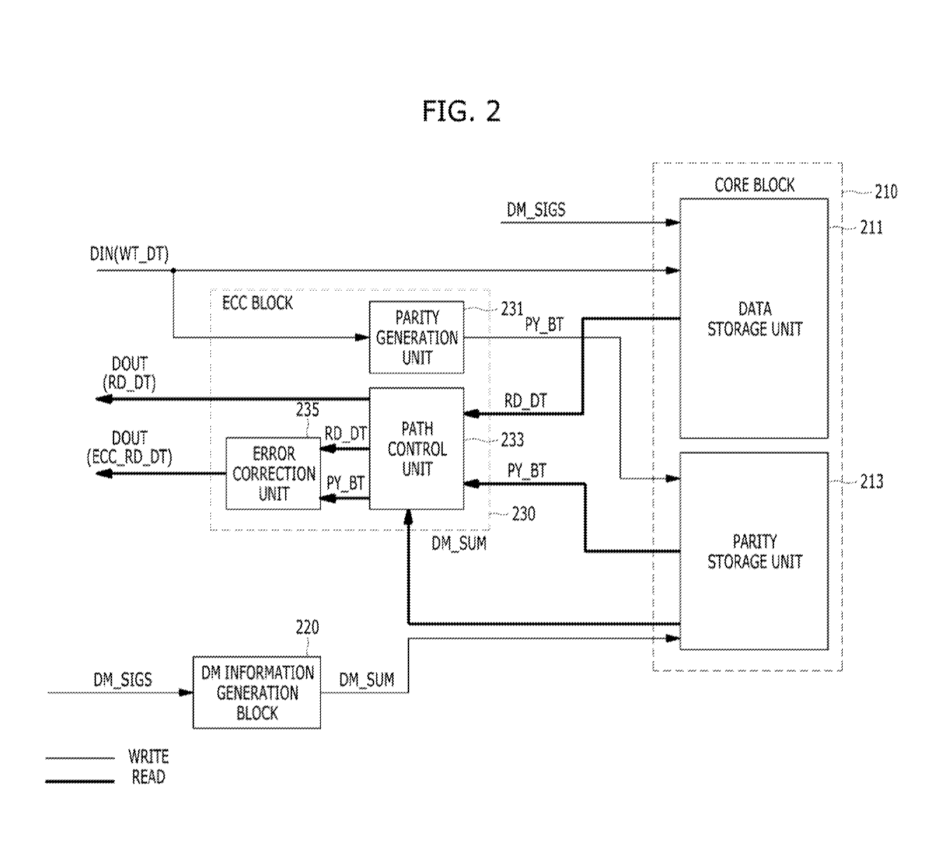

FIG. 2 is a block diagram illustrating a semiconductor memory device in accordance with an embodiment of the present invention.

Referring to FIG. 2, the semiconductor memory device may include a core block 210, a data masking (DM) information generation block 220 and an error correcting code (ECC) block 230. The core block 210 may include a data storage unit 211 and a parity storage unit 213.

The data storage unit 211 of the core block 210 may include a plurality of memory cells (not shown), and store write data WT_DT applied from an external device. The data storage unit 211 may receive a data masking signal DM_SIGS from an external device and store the write data WT_DT as normal data or combined data according to the data masking function.

Although not illustrated in FIG. 2, the core block 210 may include a plurality of write drivers for storing data into cells in the core block 210. The data masking signal DM_SIGS may be formed of a plurality of bits corresponding to the plurality of write drivers, respectively. When all bits of the data masking signal DM_SIGS are disabled, the write drivers may store the write data WT_DT as the normal data. When some bits of the data masking signal DM_SIGS are enabled and the other bits of the data masking signal DM_SIGS are disabled, the write drivers corresponding the enabled bits of the data masking signal DM_SIGS may not store the write data WT_DT and may keep the original data stored in the data storage unit 211 while the write drivers corresponding to the disabled bits of the data masking signal DM_SIGS store the write data WT_DT. Therefore, when some bits of the data masking signal DM_SIGS are enabled and the other bits of the data masking signal DM_SIGS are disabled, the data stored in the data storage unit 211 may be the combined data comprising the masked data corresponding to the enabled bits of the data masking signal DM_SIGS, i.e., the original data stored in the data storage unit 211, and the unmasked data corresponding to the disabled bits of the data masking signal DM_SIGS, i.e., the write data WT_DT. The combined data stored in the data storage unit 211 may not be the same as the write data WT_DT provided from the external device due to the masked data.

The parity storage unit 213 may store a parity bit PY_BT of the write data WT_DT generated by a parity generation unit 231. Therefore, the parity bit PY_BT corresponding to the normal data may reflect the normal data while the parity bit PY_BT corresponding to the combined data may not reflect the combined data, but the write data WT_DT included in the combined data, due to the masked data or the original data included in the combined data. Also, the parity storage unit 213 may receive masking information DM_SUM from the DM information generation block 220 and store the masking information DM_SUM.

The DM information generation block 220 may generate the masking information DM_SUM in response to the data masking signal DM_SIGS received from an external device. The DM information generation block 220 may output the masking information DM_SUM having a logic high level to the parity storage unit 213 when one or more bits of the data masking signal DM_SIGS are enabled. The masking information DM_SUM may indicate whether the current write operation is performed with the data masking function. The masking information DM_SUM having a logic high level may indicate that the data storage unit 211 stores the combined data and the parity storage unit 213 stores the parity bit PY_BT corresponding to the combined data, which does not reflect the combined data but the write data WT_DT included in the combined data due to the masked data or the original data included in the combined data. The masking information DM_SUM having a logic low level may indicate that the data storage unit 211 stores the normal data and the parity storage unit 213 stores the parity bit PY_BT corresponding to the normal data, which reflect the corresponding normal data.

The ECC block 230 may include a parity generation unit 231, a path control unit 233 and an error correction unit 235.

The parity generation unit 231 may receive the write data WT_DT and generate the parity bit PY_BT corresponding to the write data WT_DT during the write operation.

The path control unit 233 may receive read data RD_DT, which is stored in the data storage unit 211, and the parity bit PY_BT and the masking information DM_SUM, which are stored in the parity storage unit 213, during the read operation. The path control unit 233 may control output paths of the read data RD_DT and the parity bit PY_BT based on the masking information DM_SUM.

To be specific, the path control unit 233 may output the read data RD_DT or the combined data as output data DOUT without performing the ECC operation while the path control unit 233 may output the read data RD_DT or the normal data and the parity bit PY_BT to the error correction unit 235.

The error correction unit 235 may receive the read data RD_DT and the parity bit PY_BT from the path control unit 233, and may ECC decode the read data RD_DT or the normal data based on the corresponding parity bit PY_BT. The error correction unit 235 may output ECC-decoded read data ECC_RD_DT as the output data DOUT.

Hereafter, an operation of the semiconductor memory device in accordance with an embodiment of the present invention is described.

During the write operation, the data storage unit 211 may receive the write data WT_DT and the data masking signal DM_SIGS from the external device, and store the write data WT_DT as the normal data or the combined data. Simultaneously, the parity generation unit 231 may receive the write data WT_DT from the external device, and generate the parity bit PY_BT for the write data WT_DT. The parity generation unit 231 may output the parity bit PY_BT to the parity storage unit 213. The parity storage unit 213 may store the parity bit PY_BT received from the parity generation unit 231. The DM information generation block 220 may generate the masking information DM_SUM based on the data masking signal DM_SIGS, and output the masking information DM_SUM to the parity storage unit 213.

As described above, when all bits of the data masking signal DM_SIGS are disabled, the write drivers may store the write data WT_DT as the normal data. Also, when some bits of the data masking signal DM_SIGS are enabled and the other bits of the data masking signal DM_SIGS are disabled, the write drivers corresponding the enabled bits of the data masking signal DM_SIGS may not store the write data WT_DT and may keep the original data stored in the data storage unit 211 while the write drivers corresponding to the disabled bits of the data masking signal DM_SIGS store the write data WT_DT. Therefore, when some bits of the data masking signal DM_SIGS are enabled and the other bits of the data masking signal DM_SIGS are disabled, the data stored in the data storage unit 211 may be the combined data comprising the masked data corresponding to the enabled bits of the data masking signal DM_SIGS, i.e., the original data stored in the data storage unit 211, and the unmasked data corresponding to the disabled bits of the data masking signal DM_SIGS, i.e., the write data WT_DT.

Thus, when all bits of the data masking signal DM_SIGS are disabled during the write operation, the data storage unit 211 may store the write data WT_DT as the normal data, the DM information generation block 220 may generate and output the data masking signal DM_SIGS having the logic low level to the parity storage unit 213, and the parity storage unit 213 may store the parity bit PY_BT for the write data WT_DT received from the parity generation unit 231 and the masking information DM_SUM having a logic low level received from the DM information generation block 220.

During the read operation, the path control unit 233 may transmit the read data RD_DT stored as the normal data in the data storage unit 211 and the parity bit PY_BT stored in the parity storage unit 213 to the error correction unit 235 according to the masking information DM_SUM having the logic low level. The error correction unit 235 may ECC decode the normal data or the read data RD_DT based on the parity bit PY_BT. The error correction unit 235 may output the ECC-decoded read data ECC_RD_DT as the output data DOUT to an external device.

When one or more bits of the data masking signal DM_SIGS are enabled during the write operation, the data storage unit 211 may not store the write data WT_DT corresponding to the enabled bits of the data masking signal DM_SIGS, and may keep the original data stored in the data storage unit 211 while storing the write data WT_DT corresponding to the disabled bits of the data masking signal DM_SIGS in the data storage unit 211, thereby storing the combined data comprising the original data and the write data WT_DT in the data storage unit 211. However, the parity generation unit 231 may generate the parity bit PY_BT corresponding to the write data WT_DT received from an external device. The parity storage unit 213 may store the parity bit PY_BT. The parity bit PY_BT stored in the parity storage unit 213 may reflect, not the combined data, but the write data WT_DT included in the combined data. The DM information generation block 220 may receive the data masking signal DM_SIGS and generate the masking information DM_SUM having a logic high level. The parity storage unit 213 may store the masking information DM_SUM having the logic high level.

During the read operation, the path control unit 233 may output the read data RD_DT stored as the combined data in the data storage unit 211 directly to an external device without performing an error correction decoding operation according to the masking information DM_SUM having the logic high level.

Therefore, the semiconductor memory device in accordance with the embodiment of the present invention may store the masking information DM_SUM indicating whether the data stored in the data storage unit 211 is masked. Therefore, there the CAS to CAS Delay time tCCD may not be needed for write operations on both normal and masked data.

Further, in accordance with an embodiment of the present invention, the semiconductor memory device may reduce the time required for the ECC operation and error probability operations on the combined data by bypassing the ECC operation on the combined data.

While the present invention has been described with respect to specific embodiments, the embodiments are not intended to be restrictive, but rather descriptive. Further, it is noted that the present invention may be achieved in various ways through substitution, change, and modification, by those skilled in the art without departing from the scope of the present invention as defined by the following claims.

What is claimed is:

1. A semiconductor memory device, comprising:
a core block suitable for storing write data as normal data or a part of combined data according to a data masking signal, and masking information indicating data masking of the combined data; and
an error correcting code (ECC) block suitable for performing an ECC decoding operation on the normal data, and bypassing the ECC decoding operation on the combined data according to the masking information,
wherein the combined data further includes masked data.

2. The semiconductor memory device of claim 1, further comprising a data masking (DM) information generation block suitable for generating the masking information based on the data masking signal.

3. The semiconductor memory device of claim 1, wherein the ECC block includes:
a parity generation unit suitable for generating a parity bit corresponding to the write data;
an ECC unit suitable for performing the ECC decoding on the normal data based on the parity bit; and
a path control unit suitable for transferring the combined data to an external device, and the normal data to the ECC unit according to the masking information.

4. The semiconductor memory device of claim 3, wherein the core block includes:
a data storage unit suitable for storing the normal data and the combined data; and
a parity storage unit suitable for storing the parity bit and the masking information.

5. The semiconductor memory device of claim 3, wherein the path control unit transfers the normal data and the parity bit to the ECC unit when the masking information is disabled, and the combined data to the external device when the masking information is enabled.

6. A semiconductor memory device, comprising:
a core block suitable for storing write data as normal data or a part of combined data according to a data masking signal;
a data masking (DM) information generation block suitable for generating masking information indicating data masking of the combined data based on the data masking signal; and
an ECC block suitable for performing an ECC decoding operation on the normal data, and bypassing the ECC decoding operation on the combined data according to the masking information,
wherein the combined data further includes masked data.

7. The semiconductor memory device of claim 6, wherein the core block stores the write data as the normal data when the data masking signal is disabled and stores the write data as the part of the combined data when the data masking signal is enabled.

8. The semiconductor memory device of claim 7, wherein the ECC block includes:
a parity generation unit suitable for generating a parity bit corresponding to the write data;
an ECC unit suitable for performing the ECC decoding on the normal data based on the parity bit; and
a path control unit suitable for transferring the combined data to an external device, and the normal data to the ECC unit according to the masking information.

9. The semiconductor memory device of claim 8, wherein the core block includes:
a data storage unit suitable for storing the normal data and the combined data; and
a parity storage unit suitable for storing the parity bit and the masking information.

10. The semiconductor memory device of claim 8, wherein the path control unit transfers the normal data and the parity bit to the ECC unit when the masking information is disabled, and the combined data to the external device when the masking information is enabled.

11. A semiconductor memory device, comprising:
a data storage block suitable for storing normal data, on which a data masking operation is not performed, and combined data, on which the data masking operation is partly performed;
a parity storage block suitable for storing parity bits corresponding to the normal data and the combined data, respectively; and
an error correcting code (ECC) block suitable for performing an ECC decoding operation on the normal data, and bypassing the ECC decoding operation to the combined data,
wherein the combined data further includes masked data.

12. The semiconductor memory device of claim 11, further comprising a data masking (DM) information generation block suitable for generating data masking information corresponding to the combined data.

13. The semiconductor memory device of claim 12, wherein the parity storage block further stores the data masking information.

14. The semiconductor memory device of claim 13, wherein the ECC block includes:
an ECC unit suitable for performing the ECC decoding on the normal data based on the parity bit corresponding to the normal data; and
a path control unit suitable for transferring the combined data to an external device, and the normal data to the ECC unit according to the masking information.

15. The semiconductor memory device of claim 14, wherein the ECC block further includes a parity generation unit suitable for generating the parity bits.

16. The semiconductor memory device of claim 11, wherein the masked data is original data stored in the data storage block.
